(19) United States
(12) Patent Application Publication
(10) Pub. No.: US 2019/0196558 A1
(43) Pub. Date: Jun. 27, 2019

(54) SYSTEM WITH SOCKETED PROCESSING DEVICE FOR HIGH SHOCK AND VIBRATION ENVIRONMENTS

(71) Applicant: Waymo LLC, Mountain View, CA (US)

(72) Inventors: William Grossman, East Palo Alto, CA (US); Daniel Rosenband, San Jose, CA (US); Etai Bruhis, Palo Alto, CA (US)

(21) Appl. No.: 15/855,303

(22) Filed: Dec. 27, 2017

(51) Int. Cl. G06F 1/20; H05K 1/18; H05K 1/02; H05K 3/30

(52) U.S. Cl. CPC G06F 1/20; H05K 1/18; H05K 2201/10265; H05K 3/301; H05K 2201/10325; H05K 1/0203

(57) ABSTRACT

The technology provides for a system and method to secure a processing device in a socket in high shock and vibration environments, such as inside a vehicle. The processing device may be fitted in the socket, which may be soldered on a circuit board. A mounting plate may be attached to the circuit board. The processing device may be arranged between the circuit board and the mounting plate such that the processing device may be secured to the socket by a compression force applied by the mounting plate. The mounting plate may further provide cooling for the processing device.

### BACKGROUND OF THE INVENTION

Central Processing Units (CPUs) may be configured as socketed devices, meaning that the CPUs are fitted into a socket soldered onto the motherboard (PCBs). These CPUs must make contact with thousands of tiny fingers for electrical connections, and may be held into these sockets via springs of one form or another. FIG. 1 shows a typical prior art system 100 to secure a CPU in a CPU socket. The CPU is arranged between a bolster plate on one side of a PCB and a heatsink assembly on another side of the PCB. The heatsink is screwed down against a spring assembly, which tightly controls the compression force on the CPU and the pins in the socket. This compression force must be sufficient to keep the landing pads, for instance, copper contacts, on the CPU in constant contact with the pins in the socket in order to maintain electrical connections between the CPU and other components. For environments with high shocks and vibrations, such as may be expected in a vehicle, the heatsink may move and transmit all its inertial forces through the spring assembly and the bolster plate. The movements of the heatsink may reduce the compression force on the CPU, thereby causing fretting at the contact regions between the pins in the socket and the landing pads on the CPU, as well as intermittent connections. In addition, the movements of the heatsink may also cause the PCB to bend significantly, which may result in damage to the PCB. Therefore, in such environments, CPUs that come in solderable packages are typically used instead of socketed CPUs.

### BRIEF SUMMARY OF THE INVENTION

The present disclosure provides for a system, comprising a circuit board, a socket attached to the circuit board, a processing device fitted in the socket, and a mounting plate attached to the circuit board wherein the processing device is arranged between the circuit board and the mounting plate such that the processing device is secured to the socket by a compression force applied by the mounting plate.

The system may further comprise a heatsink adaptor arranged between the processing device and the mounting plate, wherein the processing device is arranged between the circuit board and the heatsink adaptor such that the processing device is secured to the socket by a second compression force applied by the heatsink adaptor.

The mounting plate may further comprise a heatsink structure arranged at least partially within the mounting plate. The heatsink structure may be a cooling channel that circulates a fluid through an interior of the mounting plate.

The mounting plate and/or the heatsink adaptor may be attached to the circuit board through a first set of fasteners and at least one bolster plate. The mounting plate may additionally be attached to the circuit board through a plurality of standoffs. The first set of fasteners may be separated from the plurality of standoffs by a predetermined lateral distance which corresponds to the compression force applied by the mounting plate meeting a predetermined minimum compression force.

The compression force applied by the mounting plate and/or the heatsink adaptor may be controlled by at least one spring assembly.

The system may further comprise a vehicle. The processing device may be a processing unit of an autonomous driving computing system of the vehicle.

The disclosure further provides for attaching a socket to a circuit board, fitting a processing device in the socket, and attaching a mounting plate to the circuit board such that the processing device is arranged between the circuit board, and such that the mounting plate and the processing device is secured to the socket by a compression force applied by the mounting plate. The method may further comprise attaching a heatsink adaptor such that the processing device is arranged between the circuit board and the heatsink adaptor, and such that the processing device is secured to the socket by a second compression force applied by the heatsink adaptor; and attaching the heatsink adaptor to the mounting plate

### BRIEF DESCRIPTION OF THE DRAWINGS

FIG. 1 illustrates a typical prior art system.

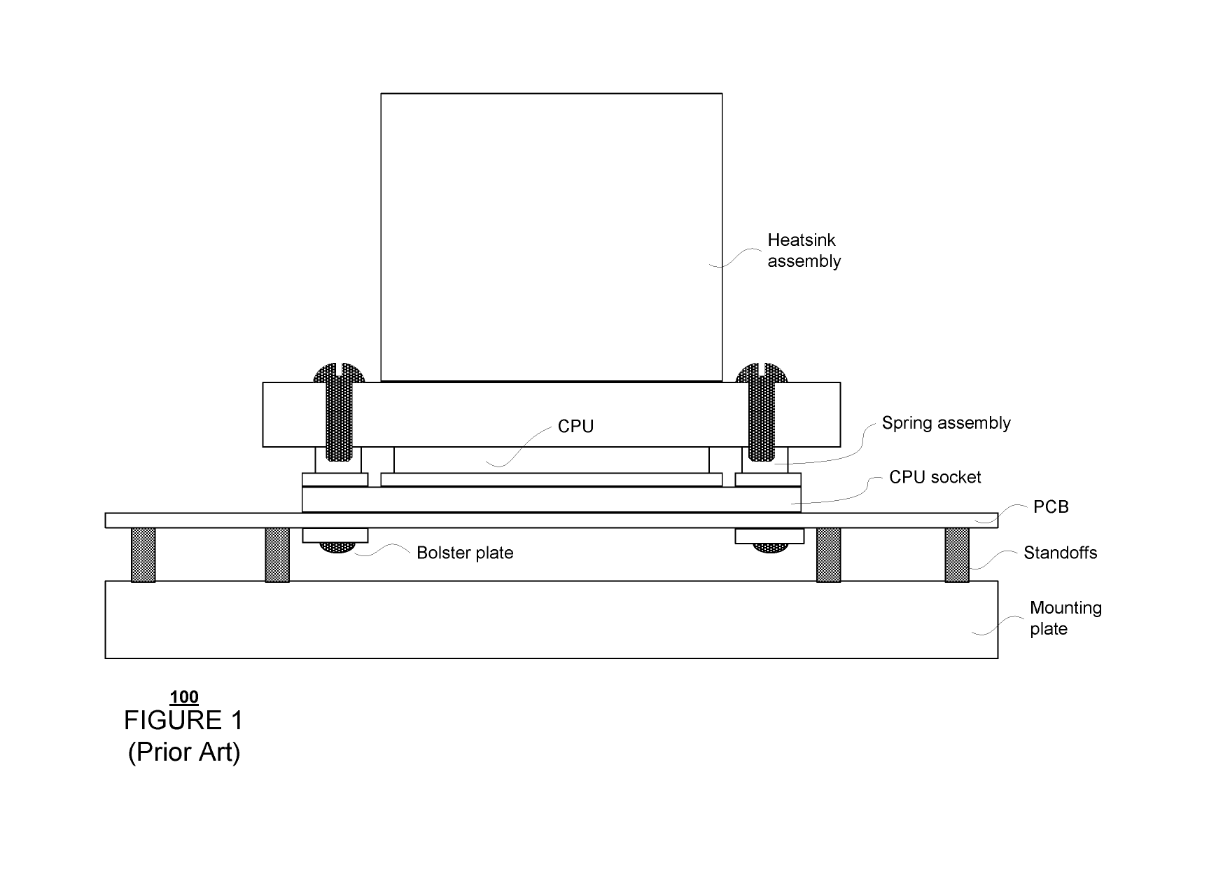

FIG. 2 illustrates an example processing device system in accordance with aspects of the disclosure.

FIG. 3 illustrates an example processing device system in accordance with aspects of the disclosure.

FIG. 4 illustrates an example processing device system in accordance with aspects of the disclosure.

FIG. 5 is a functional diagram of an example vehicle in accordance with aspects of the disclosure.

FIG. 6 is an example flow diagram illustrating an example method in accordance with aspects of the disclosure.

FIG. 7 is another example flow diagram illustrating an example method in accordance with aspects of the disclosure.

### DETAILED DESCRIPTION

### Overview

The technology relates generally to securing a socketed processing device in high shock and vibration environments, such as may be expected inside a vehicle. In particular, in a system that requires high-precision computing devices, such as in an autonomous or semi-autonomous vehicle system, the processing unit must be reliably connected to thousands of pins to ensure proper and safe operation of the vehicle. Therefore, it is critical in such a system that all the connections to the processing unit are maintained in the event of any shocks and/or vibrations likely to be encountered by the vehicle, e.g., a truck. To ensure reliable connections in such environments, a processing device may be secured to a socket on a circuit board with a necessary compression force.

An example processing device system may include a heatsink adaptor used to secure a processing device to a socket attached to a circuit board. The heatsink adaptor may apply a compression force on the processing device below the heatsink adaptor in order to keep the processing device secured in the socket. Above the heatsink adaptor, a mounting plate may be attached to the circuit board through a plurality of standoffs. The mounting plate may also include a cooling channel or a heatsink structure. The processing device may be secured in the socket by the heatsink adaptor through at least one spring assembly, a first set of fasteners, and at least one bolster plate before the mounting plate is attached to the circuit board. The heatsink adaptor may be secured to the mounting plate by a second set of fasteners. The dimensions of the various elements may be designed to better accommodate manufacturing tolerances.

In another example processing device system, a mounting plate may be used directly to secure a processing device to a socket attached to a circuit board. Here, the mounting plate may directly apply a compression force on the processing device below the mounting plate to secure the processing device to the socket. By eliminating the heatsink adaptor and, as a result, a second set of fasteners, manufacturing cost of the processing device system may be reduced. Further, the distance that heat must travel from the processing device to the mounting plate may be reduced, allowing for a more efficient heat transfer.

The features described herein may maintain a compression force required to secure a processing device to a socket and prevent damage by preventing fretting and pitting all while preventing intermittent electrical connections with the processing device. In addition, such processing device systems may further allow for processing devices to be operated at higher wattages (performance) due to the decreased thermal resistance when a processing device is directly mounted to a mounting plate with a heatsink structure, such as a cooling channel (i.e., a cold plate). Because of all this, the processing device systems described herein may be ideal for use in high shock and vibration environments such as those that are likely in vehicles, including passenger vehicles (for instance, small cars, minivans), trucks (for instance, garbage trucks, oil trucks, tractor-trailers, etc.), and busses. In particular, in a system that requires high-precision computing devices, such as in an autonomous or semi-autonomous vehicle system, the processing unit must be reliably connected to thousands of pins to ensure proper and safe operation. The connections must also be capable of withstanding shocks and vibrations encountered by the vehicle.

### Example Systems

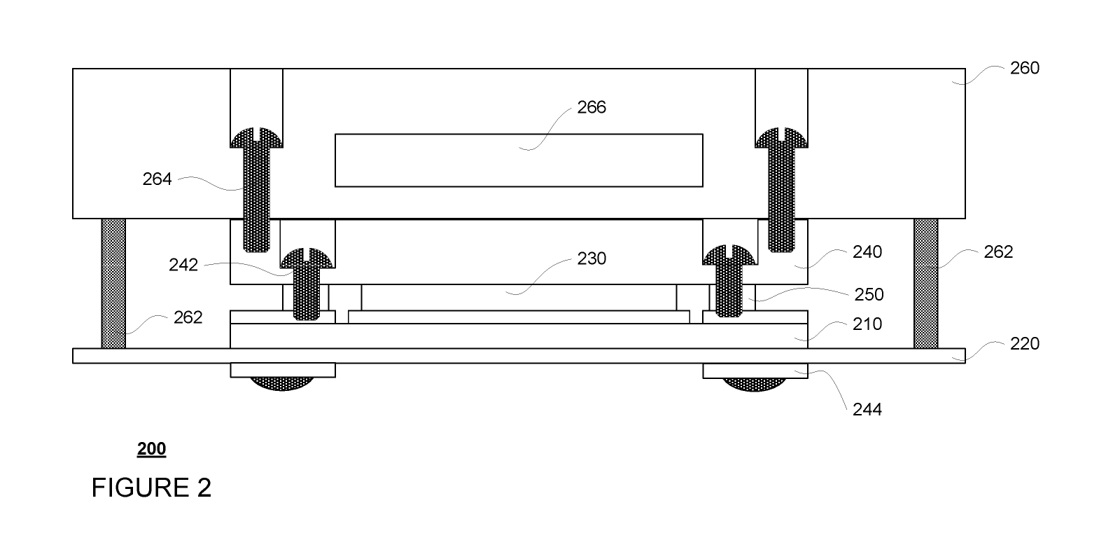

FIG. 2 shows an example processing device system 200 according to aspects of the disclosure. A socket 210 is attached onto a circuit board 220. A processing device 230 is fitted in the socket 210. The heatsink adaptor 240 is secured to the circuit board 220 through a first set of fasteners 242 and at least one bolster plate 244. The heatsink adaptor 240 may apply a compression force on the processing device 230 below the heatsink adaptor 240 in order to keep the processing device 230 secured in the socket 210. The compression force may be controlled by at least one spring assembly 250 positioned between the heatsink adaptor 240 and the circuit board 220.

Above the heatsink adaptor 240, a mounting plate 260 is attached to the circuit board through a plurality of standoffs 262. The heatsink adaptor 240 is secured to the mounting plate 260 by a second set of fasteners 264. Since both the heatsink adaptor 240 and the circuit board 220 are attached to the mounting plate 260, there may be very little movement between the heatsink adaptor 240 and the circuit board 220, which means that the compression force on the processing device 230 is better maintained during shocks and vibrations.

The circuit board 220 may be any type of board that can provide mechanical and electrical supports to electronic components. For example, the circuit board 220 may be a printed circuit board (PCB), a flexible PCB, a multiple-layer PCB, a breadboard, a stripboard, a perfboard, etc., or any combination thereof.

The processing device 230 may be any type of device that can process data. For example, the processing device 230 may be a Central Processing Unit (CPU), a graphics processing unit (GPU), a Field-Programmable Gate Array (FPGA), a microprocessor, a logic circuit, etc., or any combination thereof. For instance, the processing device may have multiple microprocessors, such a multi-core chip, or may include various types of processors housed together on one or more chips.

In the example of FIG. 2, the mounting plate 260 also includes a cooling channel 266. This cooling channel 266 may circulate fluid through an interior of the cooling channel, thereby removing excess heat from the processing device to prevent damage. The fluid may be a liquid or a gas. Alternatively, though not shown, the mounting plate 260 may have a heatsink structure on a top side of the mounting plate 260 such that the weight of the heatsink structure is supported by the mounting plate 260. For example, the heatsink structure may be fins. As yet another example, the mounting plate 260 may simply be a slab of metal capable of quickly conducting heat from the processing device 230, for instance, a 15 mm thick aluminum slab.

The configuration shown in FIG. 2 also depicts the processing device 230 to be secured in the socket 210 by the heatsink adaptor 240 through at least one spring assembly 250, the first set of fasteners 242, and at least one bolster plate 244 before the mounting plate 260 is attached to the circuit board 220. In this way, testing of the processing device 230, for instance to ensure proper functioning, etc., may be easily conducted before the mounting plate 260 is attached to the circuit board 220.

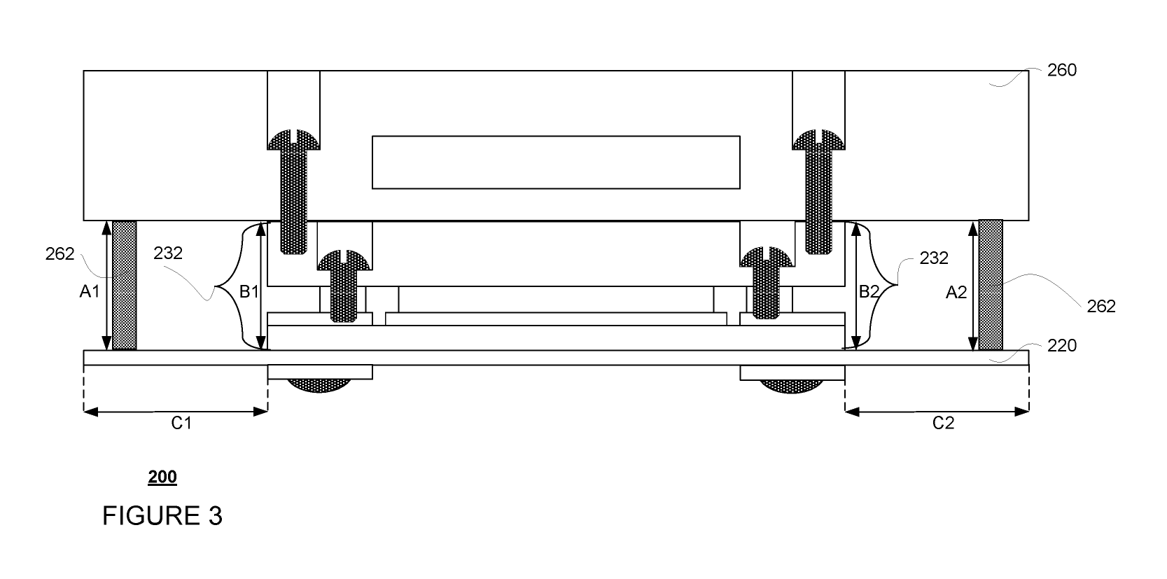

The mounting plate 260 may be substantially more rigid than the circuit board 220. For example, the mounting plate 260 may be a slab of metal, such as a 15 mm thick aluminum slab which can act as a “cold plate” to cool the processing device. As such, during shocks and vibrations, the inertial force of a processing device assembly 232 (shown in FIG. 3) including the heatsink adaptor 240, the processing device 230, the socket 210, the spring assembly 250, and the first set of fasteners 242 may be absorbed by the mounting plate 260, instead of the circuit board 220. This may decrease movement between the processing device 230 and the socket 210 which would otherwise lead to damaging effects on the pins in the socket and the landing pads on the processing device (not shown) such as fretting and pitting. Additionally, by absorbing the shocks and vibrations, the mounting plate 260 may also prevent significant bending of the circuit board 220, which helps to prevent significant changes to the compression force applied on the processing device 230, as well as preventing damage to the circuit board 220.

The dimensions of the various elements of processing device system 200 may be designed to better accommodate manufacturing tolerances. For example, referring to FIG. 3, which also depicts processing device system 200, a height A1 or A2 of the standoffs 262 may be different from a height B1 or B2 of the processing device assembly 232 including the socket 210, the processing device 230, the heatsink adaptor 240, the at least one spring assembly 250, and the first set of fasteners 242, due to manufacturing tolerances. In this example, a lateral distance C1 or C2 between the standoffs 262 and the processing device assembly 232 may be chosen such that, even in the extreme case of tolerance stackup, the compression force on the processing device 230 is still within acceptable limits specified by the processing device manufacturer.

If the lateral distance C1 or C2 is too small, then tolerance stackup differences between the height A1 or A2, and the height B1 or B2 may put large forces through the circuit board 220, causing the circuit board 220 to bend significantly. This, in turn, may change the compression force on the processing device 230. If the lateral distance C1 or C2 is too large, a significant portion of the circuit board 220 may be effectively suspended through the processing device assembly 232. In such configurations, the inertial forces during shocks and vibrations may cause fretting and intermittent electrical connections. Thus, the lateral distance C1 or C2 may be a function of the difference in the tolerance stackup of the height A1 or A2, and the height B1 or B2, a flexibility of the circuit board 220, and a predetermined minimum compression force required to keep the processing device 230 in the socket 210. Thus, each of these values may be used to calculate a predetermined lateral distance C1 or C2. In one example, the predetermined lateral distance C1 or C2 may be equal to or approximately equal to (i.e., within a predetermined threshold relative difference, such as a small percentage, 1 or 2% or more or less) the height A1 or A2.

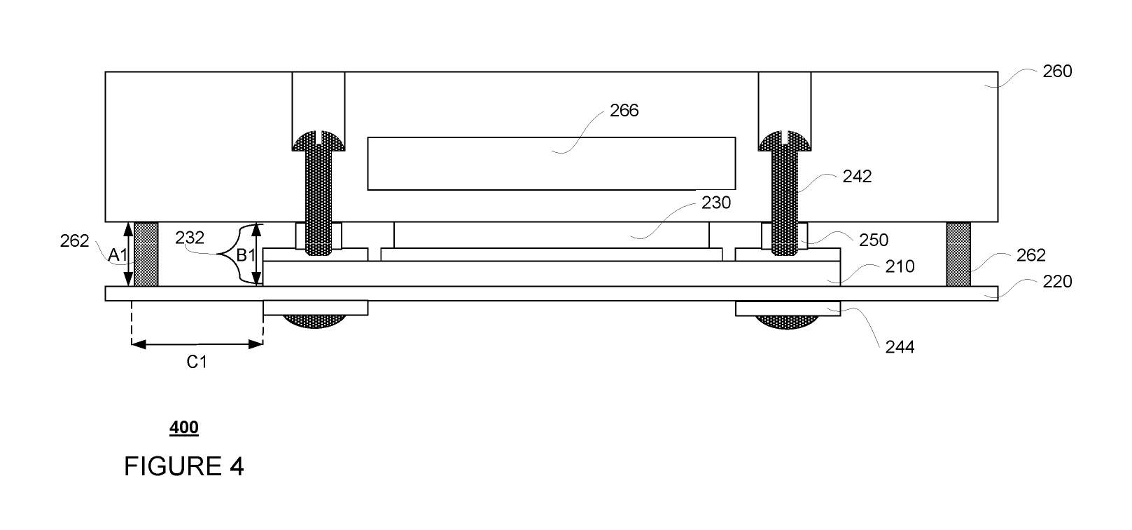

FIG. 4 shows another example processing device system 400 according to aspects of the disclosure. Processing device system 400 includes many of the features of processing device system 200 but with a different configuration than that shown in FIG. 2 as discussed further below. In this example, the mounting plate 260 is used directly to secure a processing device 230 to a socket 210. As shown, this configuration eliminates the need for a heatsink adaptor. Here, the mounting plate 260 directly applies a compression force on the processing device 230 below the mounting plate 260 to secure the processing device 230 to the socket 210. The compression force may be controlled by at least one spring assembly 250 between the mounting plate 260 and the circuit board 220.

In processing device system 400, the mounting plate 260 is secured to the circuit board 220 through a first set of fasteners 242 and at least one bolster plate 244. The mounting plate 260 is additionally attached to the circuit board 220 through a plurality of standoffs 262. The standoffs 262 may allow very little movement between the mounting plate 260 and the circuit board 220. Thus, the compression force on the processing device 230 may be better maintained during shocks and vibrations. In this example, the mounting plate 260 also has a cooling channel 266 that may circulate fluid in its interior, thereby removing excess heat from the processing device 230 to prevent damage. Alternatively, though not shown, the mounting plate 260 may have a heatsink structure on a top side of the mounting plate such that the weight of the heatsink structure is supported by the mounting plate 260.

Further, as discussed above with respect to the processing device system 200, the mounting plate 260 may be substantially more rigid than the circuit board 220 for the processing device system 400. As such, during shocks and vibrations, the inertial force of a processing device assembly 232 including the processing device 230, the socket 210, the spring assembly 250, and the first set of fasteners 242 may be absorbed by the mounting plate 260, instead of the circuit board 220.

In addition, as discussed above with respect to the processing device system 300, lateral distances C1 and C2 (only A1, B1, C1 are shown in FIG. 4 for clarity) between the standoffs 262 and the processing device assembly 232 for the example processing device system 400 may be similarly chosen such that, even in the extreme case of tolerance stackup, the compression force on the processing device 230 is still within acceptable limits specified by the processing device manufacturer.

By eliminating the heatsink adaptor 240 of the processing device system 200 and, as a result, a second set of fasteners 264, manufacturing cost of the processing device system 400 (as compared to that of processing device system 200) may be reduced. Further, the distance that heat must travel from the processing device 230 to the mounting plate 260 may also be reduced in processing device system 400 as compared to processing device system 200, allowing for a more efficient heat transfer.

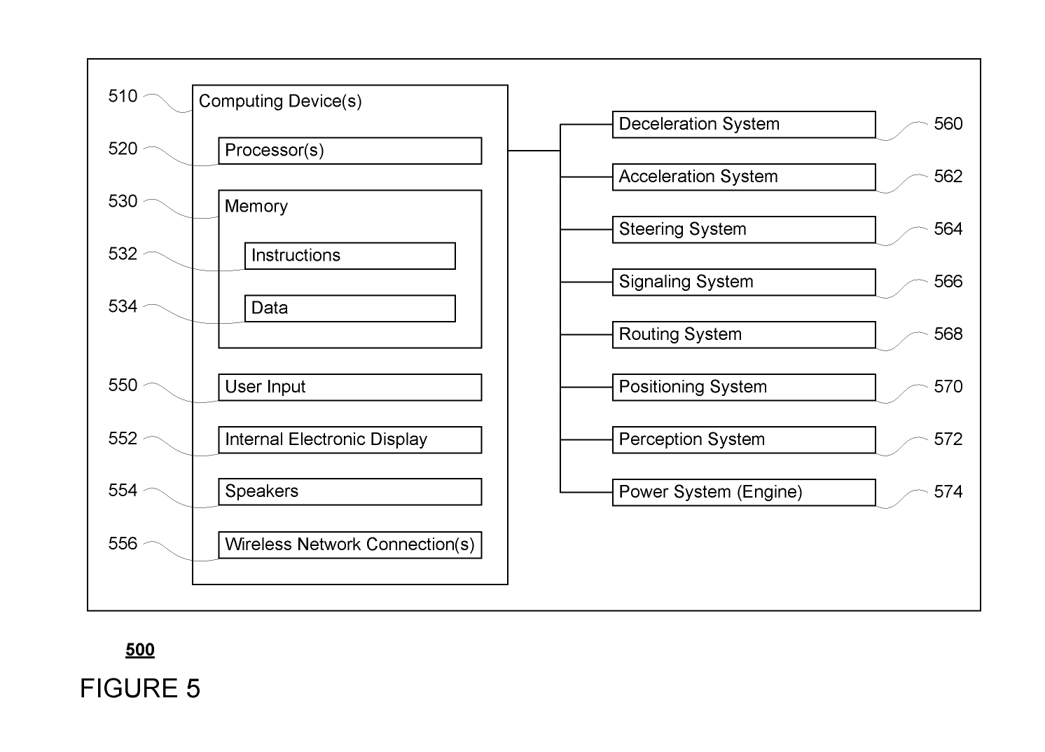

As noted above, the processing device systems 200 and 400 may be especially useful in high shock and vibration environments, such as those experienced in a vehicle. As shown in FIG. 5, an example vehicle 500 in accordance with one aspect of the disclosure includes various components. While certain aspects of the disclosure are particularly useful in connection with specific types of vehicles, the vehicle may be any type of vehicle including, but not limited to, cars, trucks, motorcycles, buses, recreational vehicles, etc. The vehicle may have one or more computing devices, such as computing devices 510 containing one or more processors 520, memory 530 and other components typically present in general purpose computing devices.

The memory 530 stores information accessible by the one or more processors 520, including instructions 534 and data 532 that may be executed or otherwise used by the processor 520. The memory 530 may be of any type capable of storing information accessible by the processor, including a computing device-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

The instructions 534 may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. Functions, methods and routines of the instructions are explained in more detail below.

The data 532 may be retrieved, stored or modified by processor 120 in accordance with the instructions 534. For instance, although the claimed subject matter is not limited by any particular data structure, the data may be stored in computing device registers, in a relational database as a table having a plurality of different fields and records, XML documents or flat files. The data may also be formatted in any computing device-readable format.

The one or more processor 520 may be any conventional processors, such as commercially available CPUs. For example, the one or more processor 520 may be configured within vehicle 500 as in any example processing device systems 200 or 400 described above, or modifications thereof. Although FIG. 5 functionally illustrates the processor, memory, and other elements of computing devices 110 as being within the same block, it will be understood by those of ordinary skill in the art that the processor, computing device, or memory may actually include multiple processors, computing devices, or memories that may or may not be stored within the same physical housing. For example, memory may be a hard drive or other storage media located in a housing different from that of computing devices 510. Accordingly, references to a processor or computing device will be understood to include references to a collection of processors or computing devices or memories that may or may not operate in parallel.

Computing devices 510 may all of the components normally used in connection with a computing device such as the processor and memory described above as well as a user input 550 (for instance, a mouse, keyboard, touch screen and/or microphone) and various electronic displays (for instance, a monitor having a screen or any other electrical device that is operable to display information). In this example, the vehicle includes an internal electronic display 552 as well as one or more speakers 554 to provide information or audio visual experiences. In this regard, internal electronic display 552 may be located within a cabin of vehicle 500 and may be used by computing devices 510 to provide information to passengers within the vehicle 500.

Computing devices 510 may also include one or more wireless network connections 556 to facilitate communication with other computing devices, such as the client computing devices and server computing devices described in detail below. The wireless network connections may include short range communication protocols such as Bluetooth, Bluetooth low energy (LE), cellular connections, as well as various configurations and protocols including the Internet, World Wide Web, intranets, virtual private networks, wide area networks, local networks, private networks using communication protocols proprietary to one or more companies, Ethernet, WiFi and HTTP, and various combinations of the foregoing.

In one example, computing devices 510 may be control computing devices of an autonomous driving computing system or incorporated into vehicle 500. The autonomous driving computing system may capable of communicating with various components of the vehicle in order to control the movement of vehicle 500 according to primary vehicle control code of memory 530. For example, returning to FIG. 5, computing devices 510 may be in communication with various systems of vehicle 500, such as deceleration system 560, acceleration system 562, steering system 564, signaling system 566, routing system 568, positioning system 570, perception system 572, and power system 574 (i.e. the vehicle's engine or motor) in order to control the movement, speed, etc. of vehicle 500 in accordance with the instructions 534 of memory 530. Again, although these systems are shown as external to computing devices 510, in actuality, these systems may also be incorporated into computing devices 510, again as an autonomous driving computing system for controlling vehicle 500.

As an example, computing devices 510 may interact with one or more actuators of the deceleration system 560 and/or acceleration system 562, such as brakes, accelerator pedal, and/or the engine or motor of the vehicle, in order to control the speed of the vehicle. Similarly, one or more actuators of the steering system 564, such as a steering wheel, steering shaft, and/or pinion and rack in a rack and pinion system, may be used by computing devices 510 in order to control the direction of vehicle 500. For example, if vehicle 500 is configured for use on a road, such as a car or truck, the steering system may include one or more actuators to control the angle of wheels to turn the vehicle. Signaling system 566 may be used by computing devices 510 in order to signal the vehicle's intent to other drivers or vehicles, for example, by lighting turn signals or brake lights when needed.

Routing system 568 may be used by computing devices 510 in order to determine and follow a route to a location. In this regard, the routing system 568 and/or data 532 may store detailed map information, for instance, highly detailed maps identifying the shape and elevation of roadways, lane lines, intersections, crosswalks, speed limits, traffic signals, buildings, signs, real time traffic information, vegetation, or other such objects and information.

Positioning system 570 may be used by computing devices 510 in order to determine the vehicle's relative or absolute position on a map or on the earth. For example, the position system 570 may include a GPS receiver to determine the device's latitude, longitude and/or altitude position. Other location systems such as laser-based localization systems, inertial-aided GPS, or camera-based localization may also be used to identify the location of the vehicle. The location of the vehicle may include an absolute geographical location, such as latitude, longitude, and altitude as well as relative location information, such as location relative to other cars immediately around it which can often be determined with less noise that absolute geographical location.

The positioning system 570 may also include other devices in communication with computing devices 510, such as an accelerometer, gyroscope or another direction/speed detection device to determine the direction and speed of the vehicle or changes thereto. By way of example only, an acceleration device may determine its pitch, yaw or roll (or changes thereto) relative to the direction of gravity or a plane perpendicular thereto. The device may also track increases or decreases in speed and the direction of such changes. The device's provision of location and orientation data as set forth herein may be provided automatically to the computing devices 510, other computing devices and combinations of the foregoing.

The perception system 572 also includes one or more components for detecting objects external to the vehicle such as other vehicles, obstacles in the roadway, traffic signals, signs, trees, etc. For example, the perception system 572 may include lasers, sonar, radar, cameras and/or any other detection devices that record data which may be processed by computing devices 510. In the case where the vehicle is a passenger vehicle such as a minivan, the minivan may include a laser or other sensors mounted on the roof or other convenient location. Additional radar units and cameras (not shown) may be located at the front and rear ends of vehicle 500 and/or on other convenient positions.

The computing devices 510 may control the direction and speed of the vehicle by controlling various components. By way of example, computing devices 510 may navigate the vehicle to a destination location completely autonomously using data from the detailed map information and routing system 568. Computing devices 510 may use the positioning system 570 to determine the vehicle's location and perception system 572 to detect and respond to objects when needed to reach the location safely. In order to do so, computing devices 510 may cause the vehicle to accelerate (for instance, by increasing fuel or other energy provided to the engine by acceleration system 562), decelerate (for instance, by decreasing the fuel supplied to the engine, changing gears, and/or by applying brakes by deceleration system 560), change direction (for instance, by turning the front or rear wheels of vehicle 500 by steering system 564), and signal such changes (for instance, by lighting turn signals of signaling system 566). Thus, the acceleration system 562 and deceleration system 560 may be a part of a drivetrain that includes various components between an engine of the vehicle and the wheels of the vehicle. Again, by controlling these systems, computing devices 510 may also control the drivetrain of the vehicle in order to maneuver the vehicle autonomously.

### Example Methods

Further to example systems described above, example methods are now described. Such methods may be performed using the systems described above, modifications thereof, or any of a variety of systems having different configurations. It should be understood that the operations involved in the following methods need not be performed in the precise order described. Rather, various operations may be handled in a different order of simultaneously, and operations may be added or omitted.

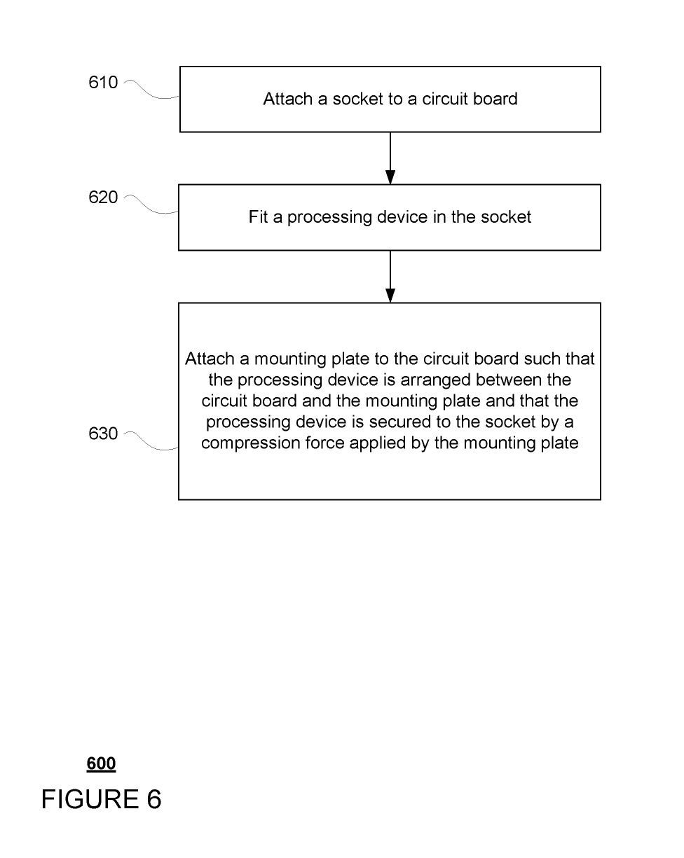

FIG. 6 illustrates an example method 600 of assembling a socketed processing device in a high shock and vibration environment. In block 610, a socket is attached to a circuit board. For example, the socket may be soldered onto the circuit board. In block 620, a processing device is fitted in the socket. In block 630, a mounting plate is attached to the circuit board so that the processing device is arranged between the circuit board and the mounting plate and that the processing device is secured to the socket by a compression force applied by the mounting plate. For example, the mounting plate may be attached to the circuit board through a first set of fasteners and at least one bolster plate. The mounting plate may be additionally attached to the circuit board through a plurality of standoffs. Further, the compression force applied by the mounting plate may be controlled by at least one spring assembly.

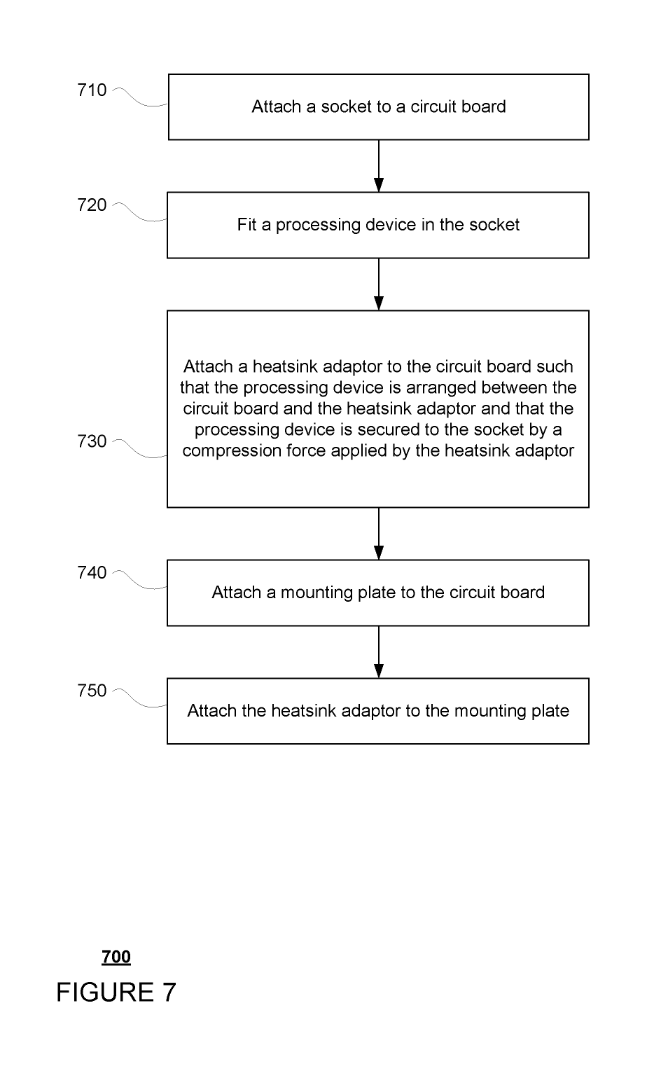

FIG. 7 illustrates another example method 700 of assembling a socketed processing device in a high shock and vibration environment. In block 710, a socket is attached to a circuit board. For example, the socket may be soldered onto the circuit board. In block 720, a processing device is fitted in the socket. In block 730, a heatsink adaptor may be attached to the circuit board such that the processing device is arranged between the circuit board and the heatsink adaptor and that the processing device is secured to the socket by a compression force applied by the heatsink adaptor. For example, the heatsink adaptor may be attached to the circuit board through a first set of fasteners and at least one bolster plate. Further, the compression force applied by the heatsink adaptor may be controlled by at least one spring assembly. In block 740, a mounting plate is attached to the circuit board. For example, the mounting plate may be attached to the circuit board through a plurality of standoffs. In block 750, the heatsink adaptor is attached to the mounting plate. For example, the heatsink adaptor may be attached to the mounting plate through a second set of fasteners.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible examples. Further, the same reference numbers in different drawings can identify the same or similar elements.

1. A system, comprising:
a circuit board;
a socket attached to the circuit board;
a processing device fitted in the socket; and
a mounting plate attached to the circuit board wherein the processing device is arranged between the circuit board and the mounting plate such that the processing device is secured to the socket by a compression force applied by the mounting plate.

2. The system according to claim 1, wherein the compression force applied by the mounting plate is controlled by at least one spring assembly.

3. The system according to claim 2, wherein the mounting plate is attached to the circuit board through a first set of fasteners and at least one bolster plate.

4. The system according to claim 3, wherein the mounting plate is additionally attached to the circuit board through a plurality of standoffs.

5. The system according to claim 1, further comprising:
a plurality of standoffs; and
a first set of fasteners separated from a plurality of standoffs by a predetermined lateral distance which corresponds to the compression force applied by the mounting plate meeting a predetermined minimum compression force.

6. The system according to claim 5, wherein a predetermined difference exists between a height of the standoffs and a height of a processing device assembly including at least the processing device and the socket.

7. The system according to claim 6, wherein the processing device assembly further includes at least one spring assembly.

8. The system according to claim 5, wherein the predetermined lateral distance is within a predetermined threshold relative difference of a height of the standoffs.

9. The system according to claim 1, wherein the mounting plate further comprises a heatsink structure arranged at least partially within the mounting plate.

10. The system according to claim 9, wherein the heatsink structure comprises a cooling channel that circulates a fluid through an interior of the mounting plate.

11. The system according to claim 1, further comprising:
a heatsink adaptor arranged between the processing device and the mounting plate;
wherein the processing device is arranged between the circuit board and the heatsink adaptor such that the processing device is secured to the socket by a second compression force applied by the heatsink adaptor.

12. The system according to claim 11, wherein the compression force applied by the heatsink adaptor is controlled by at least one spring assembly.

13. The system according to claim 12, wherein the heatsink adaptor is secured to the circuit board through a first set of fasteners and at least one bolster plate.

14. The system according to claim 11, wherein the mounting plate is attached to the circuit board through a plurality of standoffs, and a processing device assembly including at least the processing device, the socket, and the heatsink adaptor is separated from the plurality of standoffs by a predetermined lateral distance which corresponds to the second compression force applied by the heatsink adaptor meeting a predetermined minimum compression force.

15. The system according to claim 14, wherein a predetermined difference exists between a height of the standoffs and a height of the processing device assembly.

16. The system according to claim 14, wherein the predetermined lateral distance is within a predetermined threshold relative difference of a height of the standoffs.

17. The system according to claim 1, further comprising a vehicle.

18. The system according to claim 17, wherein the processing device is a processing unit of an autonomous driving computing system of the vehicle.

19. A method, comprising:
attaching a socket to a circuit board;
fitting a processing device in the socket; and
attaching a mounting plate to the circuit board such that the processing device is arranged between the circuit board, and such that the mounting plate and the processing device is secured to the socket by a compression force applied by the mounting plate.

20. The method according to claim 19, further comprising:
attaching a heatsink adaptor such that the processing device is arranged between the circuit board and the heatsink adaptor, and such that the processing device is secured to the socket by a second compression force applied by the heatsink adaptor; and
attaching the heatsink adaptor to the mounting plate.
